(19) United States
(12) Patent Application Publication
(10) Pub. No.: US 2009/0159122 A1
(43) Pub. Date: Jun. 25, 2009

(54) Leadframe Receiver Package

(75) Inventors: Gill Shook, Santa Cruz, CA (US); Hing Wah Chan, San Jose, CA (US); Michael J. Ludowise, San Jose, CA (US)

Correspondence Address: THE MUELLER LAW OFFICE, P.C., 12951 Harwick Lane, San Diego, CA, 92130, US

(73) Assignee: SolFocus, Inc., Mountain View, CA (US)

(21) Appl. No.: 12/250,034

(22) Filed: Oct. 13, 2008

Related U.S. Application Data
(63) Continuation-in-part of application No. 12/046,152, filed on Mar. 11, 2008.
(60) Provisional application No. 61/016,314, filed on Dec. 21, 2007.

(51) Int. Cl. H01L 31/00; H01L 21/00

(52) U.S. Cl. 136/256; 438/64; 257/E31.001; 257/E21.001

(57) ABSTRACT

The invention is a leadframe receiver package comprising a first conductive element, a solar cell electrically coupled to the first conductive element and comprising an active area, and a mold compound disposed on the leadframe and the solar cell. The mold compound defines a first aperture wall over at least a portion of the active area and a second aperture wall over at least a portion of the first conductive element. The mold compound includes a reflective surface to improve heat resistance around an aperture wall receiving solar radiation.

### CROSS-REFERENCE TO RELATED APPLICATIONS

This application is a continuation-in-part of U.S. patent application Ser. No. 12/046,152 filed on Mar. 11, 2008 entitled “Leadframe Receiver Package For Solar Concentrator,” which claims priority to U.S. Provisional Patent Application Ser. No. 61/016,314, filed on Dec. 21, 2007 and entitled “Leadframe Receiver Package For Solar Concentrator,” the contents of which are incorporated herein by reference for all purposes.

### BACKGROUND

As the demand for solar energy continues to increase as a source of renewable energy, concentrated solar energy collectors must be designed to operate under a wide range of climate conditions with easily manufacturable parts. Many of these parts need to withstand concentrated solar irradiation.

A solar cell is an integral component of a solar collection system and requires some manner of package for use within a power-generating system. The package must provide protection from exposure to a variety of environmental conditions and concentrated solar irradiation while providing for secure electrical connections. The package may provide heat dissipation, electrical connectivity and/or other functions to the solar cell. A concentrating solar power unit may operate to concentrate incoming light onto a solar cell. This concentrated light, which may exhibit a power per unit area of 500 or more suns, requires a solar cell package which can withstand such intensity over an operational lifetime. The package must also be capable of supporting high power levels generated by systems in which the concentrating solar power unit will typically be implemented.

Conventional attempts to address the foregoing issues have led to solar cell packages which are expensive due to material costs and/or manufacturing difficulties. What is needed is an improved solar cell package for use in a solar concentrator. Such a system may improve manufacturability, cost, operational lifetime, alignment, power generation efficiency, power dissipation and electrical isolation.

### SUMMARY

The invention provides a leadframe package that includes a solar cell with connected conductive elements encased in a mold compound with apertures for exposing the solar cell and conductive elements. The mold compound may be a reflective or heat insensitive material such as a polymer mixed with a ceramic (e.g. silica). The aperture walls surrounding the solar cell may be reflective to serve as a heat shield to surrounding components. The leadframe package may also include an optically transparent material on the active surface of the solar cell. The leadframe package may include an optical element disposed on the active surface of the solar cell.

The conductive elements may pass through one or more apertures, and there may be an insulating material such as silicone disposed in the apertures. The conductive elements may include electrical connectors. The leadframe package may include a heat spreader or a dielectric layer disposed on a portion of the leadframe package. The leadframe package may be fabricated by electrically coupling a solar cell to a conductive element and molding a mold compound to form an aperture around the solar cell and a separate aperture over at least one portion of a conductive element. The aperture wall around the solar cell may be inherently reflective, or a reflective surface may be deposited onto the aperture wall. The reflective surface can be a separate element mounted onto the leadframe package. An optical element may be co-molded into the leadframe or the mold compound may be used to align an optical element after the mold compound is cured. In some embodiments, the leadframe package may include a dielectric coating.

### BRIEF DESCRIPTION OF THE DRAWINGS

FIG. 1 is a perspective top view of a leadframe according to some embodiments.

FIG. 2A is a perspective top view of a molded package showing enclosed apertures.

FIG. 2B is a similar view of another embodiment showing two apertures open at the sides.

FIG. 2C is a similar view of another embodiment of a molded leadframe package.

FIG. 3A is a cutaway side view of a molded leadframe receiver package with a dielectric layer according to some embodiments.

FIG. 3B is a cutaway side view of another embodiment of a leadframe package with a dielectric layer.

FIG. 4A is a cutaway side view of a molded package aligning the optical element according to some embodiments.

FIG. 4B is a similar view showing the optical element co-molded in the leadframe package.

### DESCRIPTION

The following description is provided to enable any person in the art to make and use the described embodiments and sets forth the best mode contemplated for carrying out some embodiments. Various modifications, however, will remain readily apparent to those in the art. The invention provides for an improved molded leadframe package for housing a solar energy cell. The leadframe package includes an aperture with a reflective surface to assist in heat shielding the components within the leadframe package. The leadframe package provides for improved electrical insulation that may result in better performance during a high potential electrical withstand test (Hi-pot). The improved leadframe package may provide better protection against environmental conditions in a concentrated photovoltaic (CPV) system. The molded leadframe package of this invention may provide reduced manufacturing costs by minimizing the number of parts in the overall receiver design.

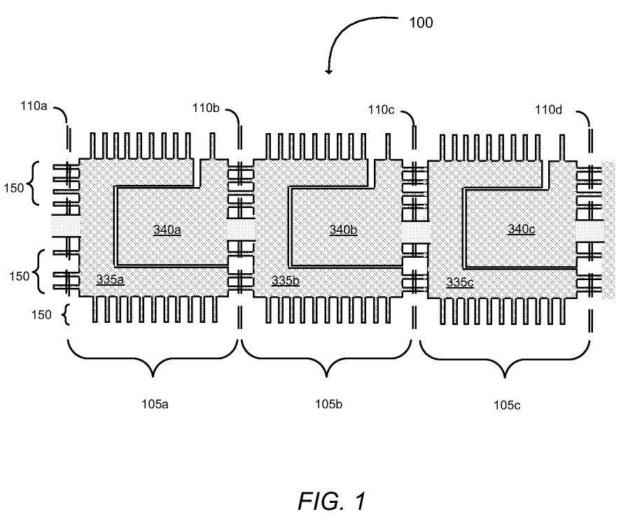

FIG. 1 is a top view of an exemplary conductive panel strip (e.g., copper) for illustration of the fabrication of a leadframe 100 that may be packaged by embodiments of the present invention. Leadframe elements of three devices 105a-105c are illustrated, but a panel strip may include elements for any number of devices. The leadframe elements 105a-105c may be etched or stamped from a conductive panel strip using known leadframe manufacturing techniques. In the embodiment of FIG. 1, leadframe 100 includes tiebar elements 150 connecting the leadframe devices 105a-105c, and also includes conductive elements 335a-335c and 340a-340c which provide electrical connections in an assembled leadframe package. Lines 110a-110d indicate cutting lines for separating leadframe components after being assembled into a molded leadframe receiver package of the present invention.

A dielectric layer may be applied to the leadframe surface at any point during the manufacture of the leadframe device. In a particular embodiment the dielectric layer may be Al₂O₃. The dielectric layer may be applied by chemical vapor deposition or any method known in the art for applying material to a leadframe. In a particular embodiment, the dielectric layer may be applied by thermal plasma spraying. The circuit pathway of the leadframe strip may be modified to facilitate one frame testing before the singulation of individual leadframe devices.

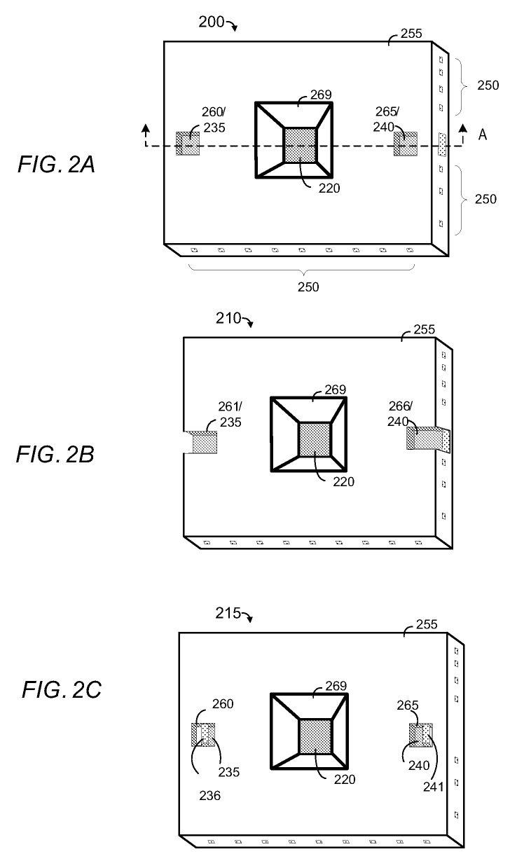

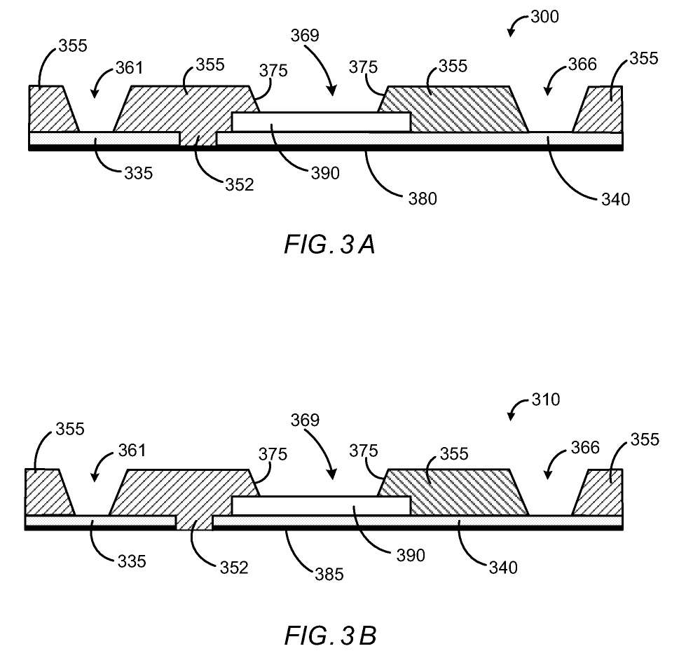

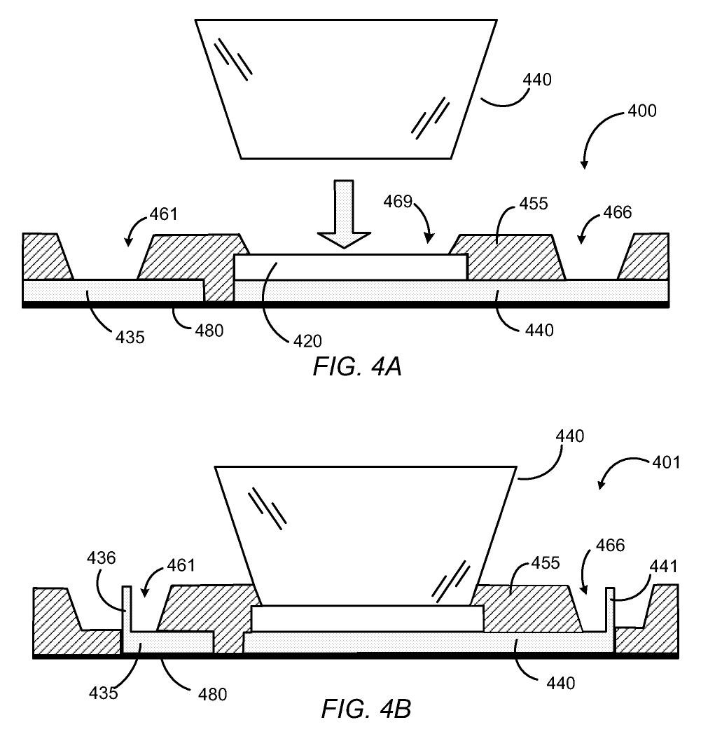

Various embodiments of assembled leadframe receiver packages of the present invention are given in the top views of FIGS. 2A-2C and the cross-sectional views of FIGS. 3A, 3B, 4A, and 4B. As shall be described subsequently in relation to these figures, solar cells (e.g. solar cell 390 of FIG. 3A-3B or solar cell 420 of FIG. 4A-4B) are attached to conductive elements 340a-340c after fabrication of the leadframe 100. A solar cell may comprise a III-V solar cell, a II-VI solar cell, a silicon solar cell, a thin film solar cell sitting on its own support element or any other type of solar cell that is or becomes known. The solar cell may comprise any number of active, dielectric and metallization layers, and may be fabricated using any suitable methods that are or become known. The solar cell is capable of generating charge carriers (i.e., holes and electrons) in response to received photons.

A solar cell used in the present invention may have conductive terminals (not shown) on its upper side. Each of the conductive terminals may comprise any suitable metal contact, and may include a thin adhesion layer (e.g., Ni or Cr), an ohmic metal (e.g., Ag), a diffusion barrier layer (e.g., TiW or TiW:N), a solderable metal (e.g., Ni), and a passivation metal (e.g., Au). These conductive terminals may be interconnected to conductive leadframe elements 340a-340c by methods such as soldering, stud bumping and wirebonding. Alternatively, interconnects may be formed by any method known in the art for attaching cell terminals to cell carriers.

A further conductive terminal (not shown) may be disposed on a lower side of the solar cell. The lower conductive terminal may exhibit a polarity opposite from the polarity of the upper conductive terminals. This lower conductive terminal may be coupled to conductive leadframe element 335a-335c using silver die attach epoxy or solder according to some embodiments. By virtue of the foregoing arrangement, current may flow between conductive elements 335 and 340 while a solar cell actively generates charge carriers. If the solar cell is faulty or otherwise fails to generate charge carriers, a bypass diode may electrically couple conductive element 335 to conductive element 340 in response to a received external signal.

FIG. 2A is a top view of an assembled leadframe package 200 according to some embodiments. Mold compound 255, which may comprise any suitable material, may be molded over the leadframe strip 100 shown in FIG. 1 or any leadframe known in the art followed by singulation of individual leadframe devices. The assembled leadframe package 200 may also include a bottom mold compound or other backing surface, not shown. In FIG. 2A, apertures 260 and 265 are defined by mold compound 255. In one embodiment apertures 260 and 265 are fully enclosed by the mold compound 255. Conductive element 235 and conductive element 240 are respectively exposed by apertures 260 and 265. The resulting package may contain exposed tiebar 250 and conductive elements 235 and 240 at the sides. The tiebars 250 may be coated with a dielectric material for insulation. Aperture 269 is disposed so as to expose an active area of solar cell 220, and the wall of the aperture 269 beneficially provides a reflective surface that may withstand exposure to concentrated solar radiation. Any percentage of the active area of solar cell 220, including 100%, may be visible through aperture 269. The surface of aperture wall 269 may be reflective to assist in directing incoming light to the active area and to prevent damage to the leadframe package 200 from light or heat. In one embodiment of this invention the material of mold compound 255 is natively reflective such as a polymer mixed with ceramic particles (e.g., silica). In another embodiment of this invention, aperture wall 269 is coated with a reflective material to form a reflective surface. According to some embodiments, the mold compound 255 is light-colored to assist in reflecting solar energy incident thereon. Mold compound 255 may have a high thermal conductivity in some embodiments and may assist in the dispersion of heat from incident solar energy.

FIG. 2B shows a top view of an embodiment of a leadframe package 210 of this invention in which apertures 261 and 266 are open at the sides of the leadframe package 210 and conductive elements 235 and 240 are exposed to the edges of the leadframe package 210. This alternative embodiment provides for a wider variety of access geometries to conductive elements 235 and 240. The mold compound of this invention may include any aperture arrangement that may cover any arrangement of leadframe and tiebar elements. Similarly, the mold compound may include mold compound covering a portion of the bottom side of the leadframe. In still another embodiment the bottom surface of the leadframe package may be laminated or coated with a dielectric material.

FIG. 2C shows another embodiment of a leadframe package 215 of this invention in which a portion 236 and 241 of conductive elements 235 and 240 may protrude into apertures 260 and 265, respectively. In this embodiment the protruding conductive portions 236 and 241 may provide for improved electrical conductivity for the leadframe package 215. The shape of the protruding portions 236 and 241 of the conductive elements 235 and 240 may be modified to facilitate electrical connection with external electrical wiring.

FIG. 3A is a cross-sectional view of a leadframe package 300 along axis of FIG. 2A. In this embodiment, the bottom surface of the leadframe package 300 is covered by a dielectric coating 380. The coating 380 may be any material known in the art to provide a thermally conductive and electrically insulative layer (e.g., Al₂O₃, diamond, BN, AlN, or SiN). The coating 380 may be applied by chemical vapor deposition, thermal spraying or any method known in the art for depositing a dielectric material. The coating 380 may be applied after the mold compound 355 has been applied to the leadframe package 300, resulting in a uniform dielectric layer 380 on the bottom surface of the leadframe package 300 covering the bottom surface of gap 352 between conductive elements 340 and 335. Also shown are apertures 361, 366 and 369. Apertures 361 and 366 expose conductive elements 335 and 340, while aperture 369 exposes an active area of solar cell 390.

One aspect of a leadframe package of this invention is that geometry of the aperture walls may result in better performance of the leadframe package during testing of safety and conductivity by providing improved insulation for the conductive elements. In another aspect, the material used to form aperture 369 may also improve the performance of the leadframe package. The wall surface 375 of aperture 369 may be reflective, resulting in reduced heating of the leadframe package 300 as concentrated sunlight is directed to the solar cell 390. The reflective wall surface 375 may be comprised of, for example, aluminum, chromium, or other reflective metals or dielectric layers. The reflective wall surface 375 may be deposited by vapor deposition or any method known in the art for depositing a material onto the surface of a mold compound. Alternatively, the wall surface 375 may be made reflective by inclusion of a separate part such as a separate piece of reflective metal insert made of aluminum or other known reflective material.

In an alternative embodiment, the reflective wall surface 375 of the aperture wall 369 may be a property of the mold compound 355. In one embodiment the mold compound 355 may be a polymer (e.g., moldable silicones and epoxies) with added particles (e.g., calcium carbonate, silica or titania). The particles may be on the order of 10's of micrometers in size. The particles may comprise 50-90% by weight of the polymer compound. In a particular embodiment, the particles may be 90% by weight of the polymer compound. In yet another particular embodiment the mold compound may be silicone with added silica particles.

FIG. 3B illustrates another embodiment of a leadframe package 310. In this embodiment, the bottom surface of only the conductive leadframe elements 335, 340 are covered by a dielectric coating 385. In this embodiment, the mold compound 355 is disposed completely through the bottom layers of the leadframe package 310 including gap 352. In an alternative embodiment, an optional bottom mold compound (not shown) which may be molded from any moldable material such as silicone may be disposed on the bottom surface of the leadframe package. In a particular embodiment the bottom mold compound is silicone. In yet another embodiment, the moldable material may be configured with variable thickness to provide a thermally conductive heat path for the solar cell 390.

In an alternative embodiment not shown, a portion of the conductive elements may be in a recessed position in the center of the leadframe package. This downset configuration may facilitate the dissipation of heat. In other embodiments, the conductive elements may be configured with variable thickness to provide a heat sink for the solar cell.

FIG. 4A is a cutaway view of a device 400 according to some embodiments. Device 400 includes conductive elements 435 and 440 which may be coupled to a dielectric layer 480, which may or may not comprise a bottom mold compound. In one embodiment layer 480 may be coupled to a heat spreader. According to other embodiments, electrical isolation between the heat spreader or other devices and conductive elements 435 and 440 may be further improved by disposing an insulator (not shown) such as silicone or epoxy within apertures 461 and 466. The aperture 469 may be filled with an optically transparent encapsulant which may provide added protection from the environment.

In one embodiment shown in FIG. 4A of this invention, an optical element 440 may be aligned by the geometry of aperture 469 in the molded compound 455. Optical element 440 may increase an acceptance angle of the concentrating solar radiation collector, homogenize incoming concentrated light over the surface of solar cell 420, and/or further concentrate the light. Aperture 469 may assist in retaining optical element 440 in a suitable position. In other embodiments, additional optical elements or optically active layers may be similarly aligned by the geometry of aperture 469 in the mold compound 455 of this invention. The additional optical layers may provide additional protection for the solar cell 420 from the environment.

FIG. 4B illustrates alternative embodiments of the present invention. In one embodiment the optical element 440 may be co-molded with the mold compound 455 into the leadframe package 401. In yet another embodiment, a portion 436, 441 of conductive elements 435, 440 may protrude into apertures 461 and 466 for improved electrical connectivity. According to other embodiments, electrical isolation of conductive elements 435 and 440 may be further improved by disposing an insulator (e.g., silicone or epoxy) within apertures 461 and 466. Insulated wires may be coupled to elements 435 and 440 through apertures 461 and 466 prior to such filling. Conductive elements 435 and 440 may comprise electrical connectors to facilitate the electrical connection with an electrical system and thereby improve the manufacturability of the invention.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention. Thus, it is intended that the present subject matter covers such modifications and variations as come within the scope of the appended claims and their equivalents.

What is claimed is:

1. An apparatus comprising:
a leadframe comprising a first conductive element;
a solar cell electrically coupled to the first conductive element and comprising an active area; and
a mold compound disposed on the leadframe and the solar cell, the mold compound forming a first aperture with a wall around at least a portion of the active area and a second aperture around at least a portion of the first conductive element; and
wherein the wall of the first aperture comprises a reflective surface.

2. The apparatus of claim 1, wherein the mold compound is a polymer.

3. The apparatus of claim 2, wherein the polymer compound is silicone.

4. The apparatus of claim 3, wherein the silicone is white.

5. The apparatus of claim 1, wherein the mold compound comprises ceramic particles.

6. The apparatus of claim 5, wherein the ceramic particles are silica.

7. The apparatus of claim 1, wherein the reflective surface is applied onto the first aperture.

8. The apparatus of claim 1, further comprising an optical element disposed in the first aperture.

9. The apparatus of claim 8, wherein the optical element is co-molded in the first aperture.

10. The apparatus of claim 1, wherein a portion of the first conductive element protrudes into the second aperture; and
wherein an insulator is disposed in the second aperture and surrounds the portion of the first conductive element.

11. The apparatus of claim 10, wherein the portion of the first conductive element comprises an electrical connector.

12. The apparatus of claim 1,
wherein the leadframe comprises a second conductive element electrically isolated from the first conductive element;
wherein the solar cell comprises:
a first conductive terminal disposed on a same side of the solar cell as the active area and exhibiting a first polarity, wherein the first conductive terminal is electrically coupled to the first conductive element; and
a second conductive terminal disposed on an opposite side of the solar cell as the active area and exhibiting a second polarity; and
wherein the mold compound defines a third aperture over at least a portion of the second conductive element and on a same side of the leadframe as the first aperture and the second aperture.

13. An apparatus comprising:
a leadframe comprising a first conductive element;
a dielectric layer disposed on a surface of the leadframe;
a solar cell electrically coupled to the first conductive element and comprising an active area; and
a mold compound disposed on the leadframe and the solar cell, the mold compound defining a first aperture wall around at least a portion of the active area and a second aperture wall around at least a portion of the first conductive element.

14. The apparatus of claim 13, wherein the dielectric layer comprises alumina (Al₂O₃).

15. A method comprising:
fabricating a leadframe comprising a first conductive element;
electrically coupling a solar cell comprising an active area to the first conductive element; and
molding a mold compound on the leadframe and the solar cell, the molded mold compound defining a first aperture around at least a portion of the active area and a second aperture around at least a portion of the first conductive element; and
forming a reflective surface in the first aperture.

16. The method of claim 15, wherein the step of forming a reflective surface in the first aperture comprises applying a reflective material to the surface of the first aperture.

17. The method of claim 16, wherein the step of forming a reflective surface in the first aperture comprises vapor deposition.

18. The method of claim 15, further comprising the step of using the geometry of the first aperture to align an optical element in the first aperture.

19. The method of claim 15, further comprising the step of co-molding an optical element in the first aperture.

20. A method comprising:
fabricating a leadframe comprising a first conductive element;
applying a dielectric layer onto a surface of the leadframe;
electrically coupling a solar cell comprising an active area to the first conductive element; and
molding a mold compound on the leadframe and the solar cell, the molded mold compound defining a first aperture around at least a portion of the active area and a second aperture around at least a portion of the first conductive element.

21. The method of claim 20, wherein the step of applying a dielectric layer to a surface of the leadframe comprises thermal spraying alumina on the surface.
